(19) United States
(12) Patent Application Publication
(10) Pub. No.: US 2006/0286800 A1
(43) Pub. Date: Dec. 21, 2006

(54) Method for adhesion and deposition of metal films which provide a barrier and permit direct plating

(76) Inventors: Juan E. Dominguez, Hillsboro, OR (US); Michael L. McSwiney, Scappoose, OR (US); Steven W. Johnston, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/154,151

(22) Filed: Jun. 15, 2005

(51) Int. Cl. H01L 21/44

(52) U.S. Cl. 438/680

(57) ABSTRACT

A method for fabricating a barrier layer and a barrier layer is described which employs a metal selected from the group of Ru, Ir, Pd, Pt, Rh, Os, Au, Ag, W, Ta and Ti. A graded region is formed to cause the metal to adhere to an underlying substrate. Direct plating is enabled without a seed layer.

### FIELD OF THE INVENTION

The invention related to forming of barrier layers and seed layers in semiconductor processing such as are used in a damascene process.

### PRIOR ART AND RELATED ART

Some thin metal films, including certain noble metals, have been identified as key enablers for permitting direct plating onto a barrier layer, thereby eliminating a separate seed layer. This is discussed in “Forming a Copper Diffusion Barrier,” Pub. No. US2004/0084773. Unfortunately, in many cases these metals do not adhere well to, for instance, an underlying dielectric layer. The use of a more standard barrier, such as TaN, underlying the noble metal layer provides adhesion but at the cost of the complexities associated with forming the TaN layer. Moreover, TaN depositions have inherent resist poisoning problems.

### BRIEF DESCRIPTION OF THE DRAWINGS

FIG. 1 is a cross-section, elevation view of a semiconductor substrate showing an underlying conductor and an opening in an interlayer dielectric (ILD) layer formed above the conductor.

FIG. 2 is a diagram illustrating a graded interface between an underlying layer and a pure metal layer formed from specified metals discussed below.

FIG. 3 is a cross-sectional, elevation view of a fabrication chamber showing certain precursors and reactive gases being introduced into the chamber.

FIG. 4 is a cross-sectional, elevation view of the structure of FIG. 1 following the formation of a metal layer, such as a copper layer.

FIG. 5 illustrates the structure of FIG. 4 following planarization.

### DETAILED DESCRIPTION

A method and layer are described for providing a barrier layer which enables direct plating without a separate seed layer. In the following description, numerous specific details are set forth such as specific precursors, in order to provide a thorough understanding of the present invention. It will be apparent to one skilled in the art, that the process described may be practiced without these specific details. In other instances, well-known processing steps, such as etching and cleaning steps, are not described in detail in order to not unnecessarily obscure the description which follows.

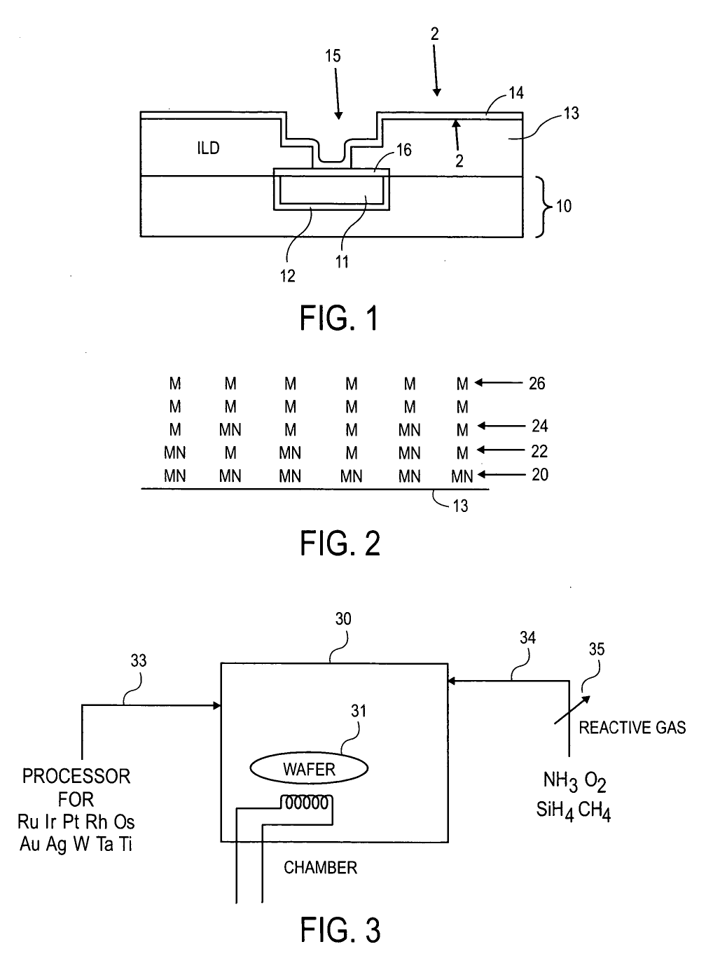

In FIG. 1, a first interconnect level 10 is shown having a conductor 11 lined with a barrier layer 12 and capped with a capping layer 16. By way of example, the conductor 11 may be a copper or copper alloy conductor lined with a typical barrier metal such as a TaN, and capped with a selectively deposited cobalt layer 16. The barrier layer 12 may instead be a barrier layer such as described below.

An ILD 13 is formed over the interconnect level 10 and may, for example, be a silicon dioxide layer or low-k carbon-doped oxide layer. Other ILD materials may be used such as an organic-based polymer layer. An opening 15 is etched into the ILD 13, the opening having a via opening exposing the capping layer 16, and a wider trench opening for a conductor. Note, while in FIG. 1 the opening 15 is shown exposing an underlying conductor 11, it may just as well expose other integrated circuit features such as a gate or doped region.

The opening 15, as well as the upper surface of the ILD 13 of FIG. 1, are lined and covered with a layer 14. As described in detail below, and as shown in FIG. 2, the layer 14 provides a barrier to prevent subsequently plated metal, such as copper, from diffusing into the ILD 13. Moreover, at least the upper surface of layer 14 is a pure metal region, or relatively pure metal region, which provides sufficient electrical conduction to allow the subsequently plated metal to be formed without the use of a seed layer.

Certain specified metals, as described below, may be used in the formation of the layer 14. Some of these metals are often referred to as platinum metals, some as noble metals, some as transitional metals, and some as precious metals. For purposes of the description below, when the term “specified metals” is used, it refers to Ru, Ir, Pd, Pt, Rh, Os, Au, Ag, W, Ta and Ti.

In FIG. 2, the surface of the layer 13 is shown along with several atomic-level layers (nano-layers) which comprise the layer 14 of FIG. 1. While the graded metal layer of FIG. 2 is shown on the ILD 13, it may also be formed on a treated surface as will be described below, or for that matter, on a more ordinary barrier such as a TaN barrier.

The nano-layer 20 which is formed directly on the underlying ILD 13 includes, for purposes of explanation, an equal number of “M” and “Ns.” This indicates that the nano-layer 20 has, again for purposes of explanation, an equal number of specified metal atoms, and atoms of nitrogen. (As will be discussed “N” could also be silicon, oxygen or carbon.) The next higher nano-layer 22 includes fewer “Ns” and more “Ms.” In the nano-layer 24, when compared to nano-layer 22, it has fewer “Ns” and more “Ms.” Finally, the nano-layer 26 and the nano-layer above it includes just “Ms,” that is, it is a pure metal layer, although it may include some atoms of nitrogen, oxygen, silicon or carbon. The structure of FIG. 2 is referred to as a graded region of a specified metal M. This graded region provides improved adhesion between the pure metal and ILD.

Where the underlying layer (such as ILD 13) which receives the graded region includes carbon, a reactive gas may be used to treat the surface prior to the formation of a graded region. Such silicon containing layers may be without limitation a low-k (carbon doped) dielectric or silicon dioxide layer. This treatment comprises the creation of a secondary phase at the surface of the silicon containing layer by the introduction of a reactive gas (e.g. O₂, CH₄) into the deposition chamber.

Also atomic layer deposition (ALD) or chemical vapor deposition (CVD) may also be used to deposit silicon containing nanolaminate films with selected compositions and thicknesses. The nanolaminate can be deposited on the silicon containing surface using a combination of silicon precursors and any one of a number of carbon containing or nitrogen containing atmospheres. The silicon precursors may include aminosilanes, silizanes, azidosilanes, silyl methanes and silyl ethanes with substitutions and additions thereof. The same result can be achieved by a nano-layer-by-nano-layer deposition of silicon, oxygen and carbon in appropriate ratios, from gases such as CH₄, Co and SiH₄.

The use of the above described surface treatment will result in the formation of a silicon based film such as, but not limited to SiN, SiON, SiCN, SiCON and SiC. These phases can act both as adhesive layers and diffusion barriers. Depending on the phase stacking desired at the surface of the silicon containing layer, different reactive gases can be introduced into the chamber to produce the desired nanolaminate surface with graded composition. The layers can also be utilized to seal micropores in low-k materials. The total thickness of these layers ideally is minimized (e.g. 10-25 Å) in order not to impact the overall film stack k value (k equal to or less than 5.0 is desired). After the modified surface layer is obtained, the pure specified metal is deposited, as described below, with a graded region.

Referring now to FIG. 3, the graded region leading to the pure specified metal barrier layer can be formed in an ordinary chamber 30, such as an ALD or CVD (or plasma enhanced CVD) chamber. As shown by line 33, a precursor provides atoms of the specified metal to the chamber. A reactive gas such as ammonia, oxygen, silane or methane are provided through a line 34. The valve 35 is used to demonstrate that the reactive gas is only used during the initial phases of the deposition and is cut off after the first few metal nano-layers of the graded material are deposited, as shown in FIG. 2. Then, the pure bulk specified metal continues to complete the barrier layer. The nano-layers 20-24 of FIG. 2, as formed in the chamber 30 of FIG. 3, may include metal oxide, nitride, carbide, silicides, or combination thereof, such as oxynitride, to improve adhesion of the subsequently deposited pure specified metal. Additionally, the layers as shown in FIG. 2, may be used to seal micropores in, for instance, a low-k material to improve adhesion.

The deposition of the specified metals using physical vapor deposition, CVD and ALD is well known. For example the deposition of ruthenium is described in Y. Matsui et al., Electro. And Solid-State Letters, 5, C18 (2002) using Ru(EtCp)2. The use of [RuC5H5(CO)2]2,3 to deposit ruthenium is described in K. C. Smith et al., Thin Solid Films, v376, p. 73 (November 2000). The use of Ru-tetramethylhentane dionate and Ru(CO)6 to deposit ruthenium is described in http://thinfilm.snu.ac.kr/research/electrode.htm.

The deposition of rhodium is described in A. Etspuler and H. Suhr, Appl. Phys. A, vA48, p. 373 (1989) using dicarbonyl(2,4-pentanedionato)rhodium-(I).

The deposition of molybdenum is described in K. A. Gesheva and V. Abrosimova, Bulg. J. of Phys., v19, p. 78 (1992) using Mo(Co)6.

The deposition of molybdenum using MoF6 is described in D. W. Woodruff and R. A. Sanchez-Martinez, Proc. of the 1986 Workshop of the Mater. Res. Soc., p. 207 (1987).

The deposition of osmium is described in Y. Senzaki et al., Proc. of the 14.sup.th Inter. Conf. And EUROCVD-11, p. 933 (1997) using Os(hexafluoro-2-butyne)(CO)4.

The deposition of palladium is described in V. Bhaskaran, Chem. Vap. Dep., v3, p. 85 (1997) using 1,1,1,5,5,5-hexafluoro-2,4-pentanedionato palladium(II) and in E. Feurer and H. Suhr, Tin Solid Films, v157, p. 81 (1988) using allylcyclopentadienyl palladium complex.

The deposition of platinum is described in M. J. Rand, J. Electro. Soc., v122, p. 811 (1975) and J. M. Morabito and M. J. Rand, Thin Solid Films, v22, p. 293 (1974) using Pt(PF3)4) and in the Journal of the Korean Physical Society, Vol. 33, November 1998, pp. S148-S151 using ((MeCp)PtMe.sub.3) and in Z. Xue, H. Thridandam, H. D. Kaesz, and R. F. Hicks, Chem. Mater. 1992, 4, 162 using ((MeCp)PtMe.sub.3).

The deposition of gold is described in H. Uchida et al., Gas Phase and Surf. Chem. of Electro. Mater. Proc. Symp., p. 293 (1994) and H. Sugawara et al., Nucl. Instrum. and Methods in Physics Res., Section A, v228, p. 549 (1985) using dimethyl(1,1,1,5,5,5-hexafluoroaminopenten-2-on-ato)Au(III).

The deposition of iridium has been described using (Cyclooctadiene) Iridium (hexafluoroacetylacetonate).

Following the deposition of the graded specified metal and the pure bulk portion of the layer 14, post deposition annealing may be used. This may include laser annealing, thermal annealing or plasma annealing. This enhances the graded regions interdiffusion and adhesion to the underlying layer. Post-deposition annealing using reduction/oxidizing conditions of the metal for grain growth and adhesion enhancement to modified silicon surfaces may also be used.

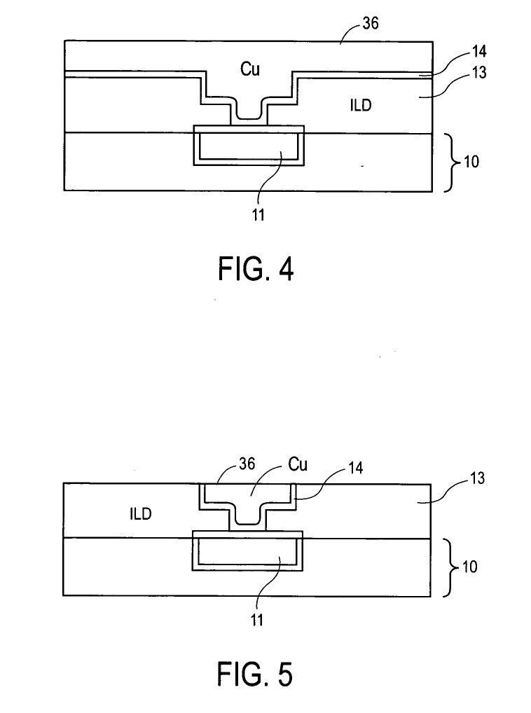

As shown in FIG. 4, a conductive metal layer 36 such as a copper layer, is plated over the barrier layer 14 using ordinary electroplating. The annealing steps described above may be performed at this point in the processing to better adhere the layer 14 to the ILD 13. Alternatively, the annealing may be performed prior to the formation of the layer 36.

Following the formation of the layer 16 as shown in FIG. 5, the layer 36 and the barrier metal layer 14, to the extent that they are on the upper surface of the ILD 13, are planarized using, for instance, chemical mechanical polishing (CMP) to provide the structure shown in FIG. 5. Following this, a capping layer such as a cobalt layer may be formed over the conductive layer 36, or an etchant stop layer may be formed, as is sometimes used where additional interconnect levels are to be fabricated.

Thus, improved adhesion for a pure specified metal to an underlying surface has been described where the specified metal can act as a diffusion barrier to, for instance, copper and provide a layer suitable to permit direct plating without a seed layer.

What is claimed is:

1. A method comprising:
introducing a precursor for forming a metal selected from the group consisting of Ru, Ir, Pd, Pt, Rh, Os, Au, Ag, W, Ta and Ti, into a chamber; and
introducing a reactive gas into the chamber during the initial deposition of the metal so as to form a graded region in the initially deposited region of the metal and a substantially pure bulk region of the metal, the graded region including atoms selected from the group consisting of silicon, carbon, oxygen and nitrogen.

2. The method defined by claim 1, wherein the chamber is part of a chemical vapor deposition apparatus.

3. The method defined by claim 1, wherein the chamber is part of an atomic layer deposition apparatus.

4. The method defined by claim 1, wherein the graded and bulk metal regions are formed in openings defined in a dielectric layer on a semiconductor wafer.

5. The method defined by claim 1, wherein the graded and bulk metal regions are formed on a barrier layer disposed within openings defined on a semiconductor wafer.

6. The method defined by claim 1, wherein the reactive gas is selected from the group consisting of NH₃, O₂, SiH₄, and CH₄.

7. The method defined by claim 1, including annealing following the deposition of the bulk region of the metal.

8. A method in semiconductor processing comprising:
forming an opening in a dielectric layer; and
forming a barrier layer in the opening to prevent diffusion of a subsequently deposited conductor into the dielectric layer, including forming a graded region between the dielectric layer and the barrier layer, the barrier layer comprising a metal selected from the group consisting of Ru, Ir, Pd, Pt, Rh, Os, Au, Ag, W, Ta and Ti, the graded region having atoms selected from the group consisting of silicon, carbon, oxygen and nitrogen.

9. The method defined by claim 8, including annealing the barrier layer.

10. The method defined by claim 8, wherein the dielectric layer comprises a silicon-containing layer.

11. The method defined by claim 10, wherein prior to the forming of the barrier layer, the dielectric layer is treated with a reactive gas to modify the surface of the dielectric layer.

12. The method defined by claim 11, wherein the treatment comprises creating a secondary phase at the surface of the silicon-containing layer by the introduction of the reactive gas.

13. The method defined by claim 12, wherein the reactive gas is carbon or nitrogen containing.

14. The method defined by claim 8, wherein the dielectric layer contains silicon and a nanolaminate layer is formed on the silicon containing dielectric layer using a silicon precursor and a reactive gas containing carbon or nitrogen.

15. The method defined by claim 14, wherein the silicon precursor is selected from the group consisting of aminosilanes, silazanes, azidosilanes, silyl methands and silyl ethanes.

16. The method defined by claim 8, wherein after the forming of the opening and prior to the formation of the barrier layer, a silicon based layer is formed selected from the group consisting of SiN, SiON, SiCN, SiCON and SiC.

17. A structure in a semiconductor comprising:
a dielectric layer,
a barrier layer of a metal selected from the group consisting of Ru, Ir, Pd, Pt, Rh, Os, Au, Ag, W, Ta and Ti, and a graded region between the dielectric layer and barrier layer comprising a combination of atoms of the metal layer and atoms selected from the group consisting of silicon, carbon, oxygen, and nitrogen.

18. The structure defined by claim 17, wherein the metal layer and the graded regions are formed in openings defined in the dielectric layer.

19. The structure defined by claim 18, wherein the opening includes via openings and which expose an underlying conductor.

20. The structure defined by claim 19, wherein the dielectric layer includes silicon.
